(19) United States
(12) Patent Application Publication
(10) Pub. No.: US 2014/0145294 A1
(43) Pub. Date: May 29, 2014

(54) WAFER SEPARATION

(71) Applicant: NXP B.V., Eindhoven (NL)

(72) Inventors: Sascha Moeller, Hamburg (DE); Martin Lapke, Hamburg (DE)

(73) Assignee: NXP B.V., Eindhoven (NL)

(21) Appl. No.: 13/687,110

(22) Filed: Nov. 28, 2012

(51) Int. Cl. H01L 27/04; H01L 21/78

(52) U.S. Cl. CPC H01L 27/04; H01L 21/78
USPC 257/499; 438/463

(57) ABSTRACT

A method is provided for separation of a wafer into individual ICs. Channels are formed in the one or more metallization layers on a front-side of the wafer along respective lanes. The lanes are located between the ICs and extend between a front-side of the metallization layers and a backside of the substrate. A backside of the substrate is thinned, and laser pulses are applied via the backside of the substrate to change the crystalline structure of the silicon substrate along the lanes. The plurality of portions in the silicon substrate and the channels are configured to propagate cracks in the silicon substrate along the lanes during expansion of the IC wafer. The channels assist to mitigate propagation of cracks outside of the lanes in the metallization layers during expansion of the IC wafer.

Aspects of the present disclosure relate to apparatuses, devices, and methods for separation of a wafer.

Integrated circuits (ICs) are typically produced by forming a plurality of ICs on a semiconductor substrate, such as silicon. The ICs include one or more layers formed on the substrate (e.g., semiconductor layers, insulative layers, and metallization layers). The individual ICs are separated by lanes. The finished ICs on the wafer are then separated into individual ICs by, for instance, sawing the wafer along the lanes. Separation of the wafer into individual ICs may be referred to as dicing. Sawing may be performed using various mechanical cutting and laser cutting methods. Mechanical cutting tools tend to cause chipping of the backside of a substrate. Laser cutting tends to cut unevenly in metallization layers formed on a front-side of the substrate.

Aspects of the present disclosure relate to separation of ICs on a silicon wafer. In one embodiment, a method is provided for dicing a wafer into separate ICs. The wafer includes a silicon substrate and metallization layer(s) on a front-side of the silicon substrate. Channels are formed in the metallization layer(s) along respective lanes. The lanes are located between ICs and extend between a front-side of the metallization layer(s) and a backside of the silicon substrate. After a backside of the silicon substrate is thinned, crystalline structure of portions of the silicon substrate located within the lanes are modified by applying a laser via the backside of the silicon substrate. The portions are offset from the backside of the silicon substrate and from the metallization layer(s).

The ICs are separated along the lanes by expanding the silicon substrate while using the changed crystalline structure and the channels to propagate cracks in the silicon substrate along the lanes, and mitigate cracking of the silicon substrate and metallization layer in regions outside of the lanes.

In another embodiment, an IC wafer configured to facilitate separation of the wafer into individual ICs is provided. The wafer includes a silicon substrate and metallization layer(s) on a front-side of the silicon substrate. Channels are formed in the metallization layers along respective lanes. The lanes are located between a plurality of ICs on the wafer and extend between a front-side of the metallization layers and a backside of the silicon substrate. A plurality of portions in the silicon substrate, located within the lanes, have a crystalline structure that is different from a crystalline structure of the silicon substrate outside of the lane. The plurality of portions in the silicon substrate and the channels are configured to propagate cracks in the silicon substrate along the lanes and mitigate propagation of cracks outside of the lanes during expansion of the IC wafer.

While the disclosure is amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the scope of the disclosure including aspects defined in the claims.

Aspects of the present disclosure may be more completely understood in consideration of the detailed description of various embodiments of the present disclosure that follows in connection with the accompanying drawings, in which:

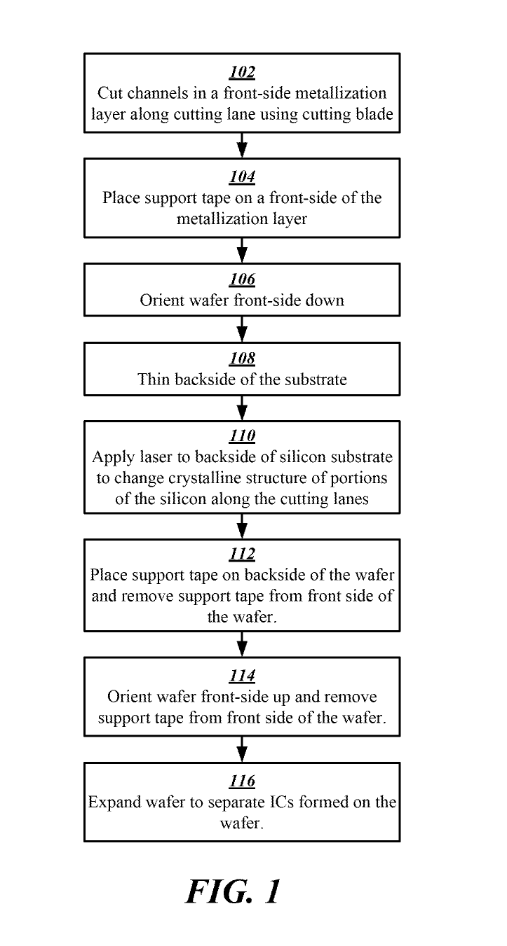

FIG. 1 shows a flowchart of a method for separating ICs formed on a wafer, in accordance with one or more embodiments;

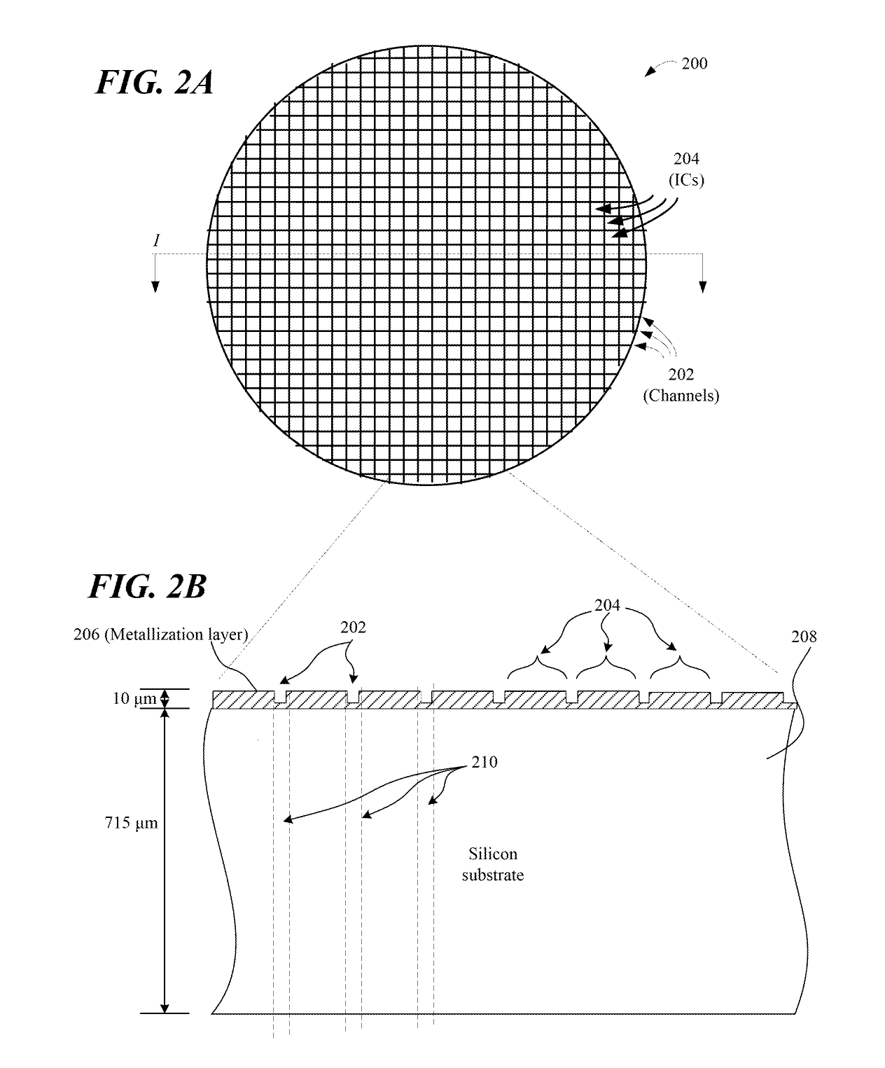

FIGS. 2-9 illustrate separation of ICs formed on a wafer according to the flow shown in FIG. 1;

FIGS. 2A and 2B show top and cross-sectional views of a wafer having channels cut in a front-side metallization layer along separation lanes of the wafer;

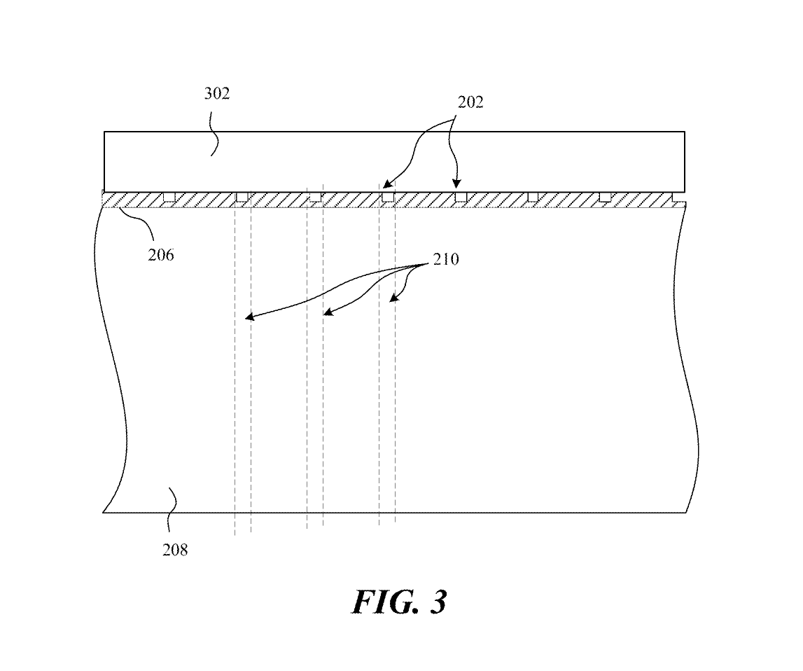

FIG. 3 shows the wafer of FIG. 2 with support tape placed on the front-side of the wafer;

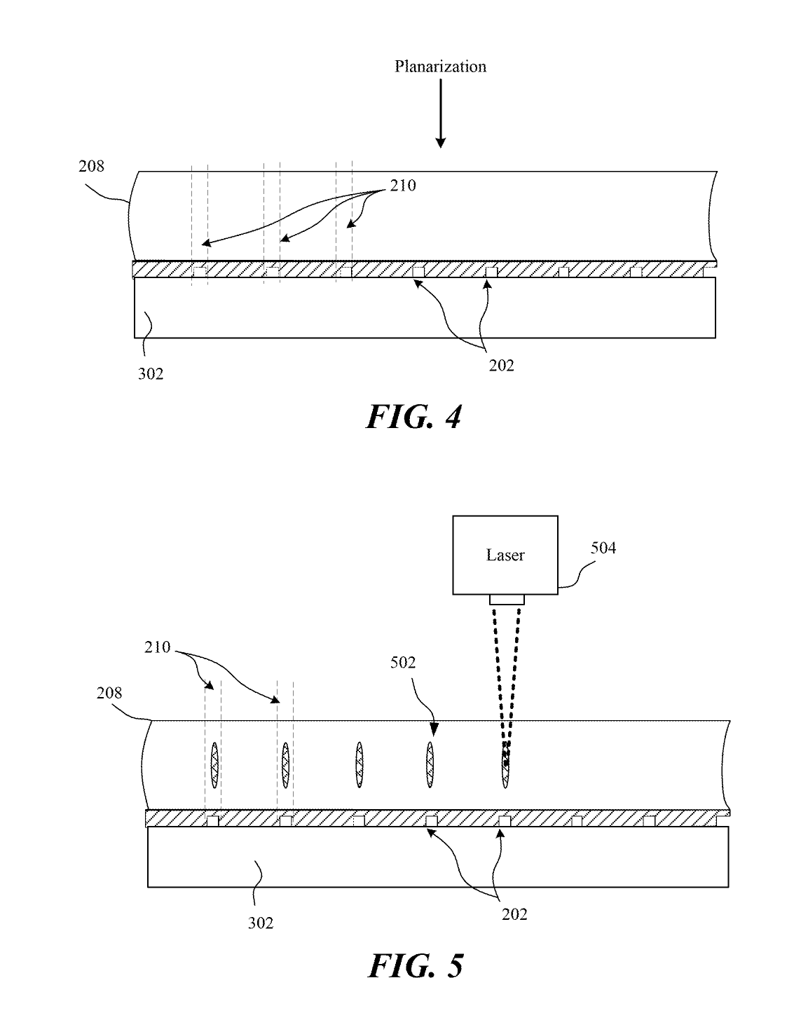

FIG. 4 shows the wafer of FIG. 3 oriented front-side down with the backside of the silicon substrate thinned;

FIG. 5 shows the wafer of FIG. 4 with crystalline structure changed in portions of the silicon substrate along the lanes of the wafer;

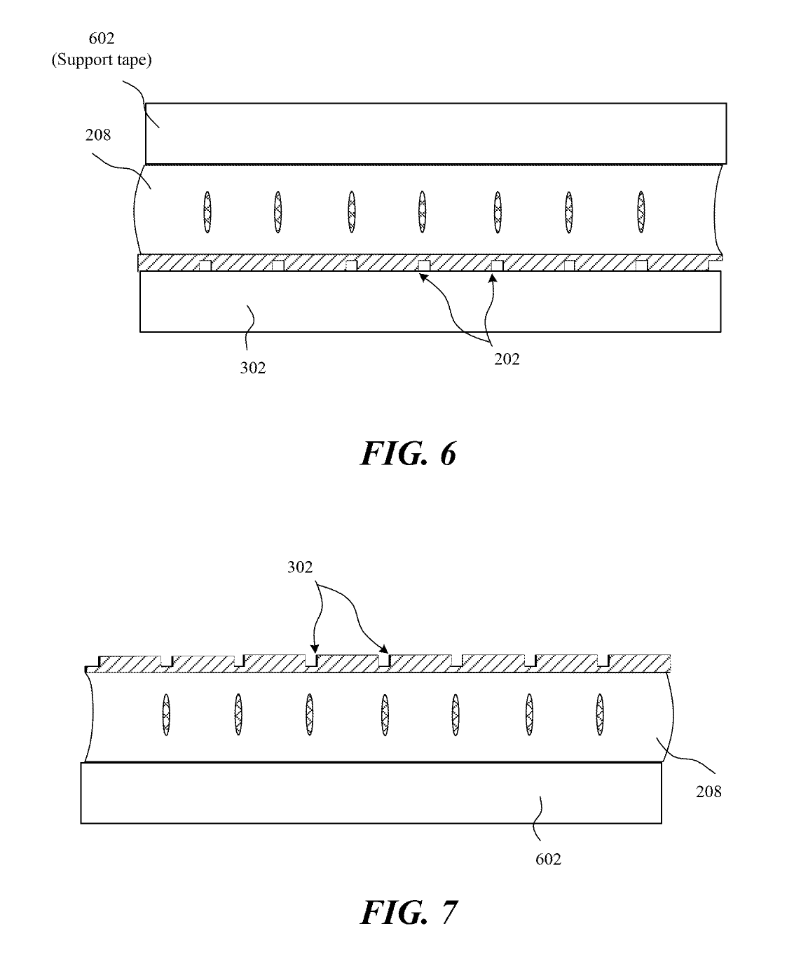

FIG. 6 shows the wafer of FIG. 5 with support tape placed on the backside;

FIG. 7 shows the wafer of FIG. 6 place backside down with the support tape removed from the front-side of the wafer;

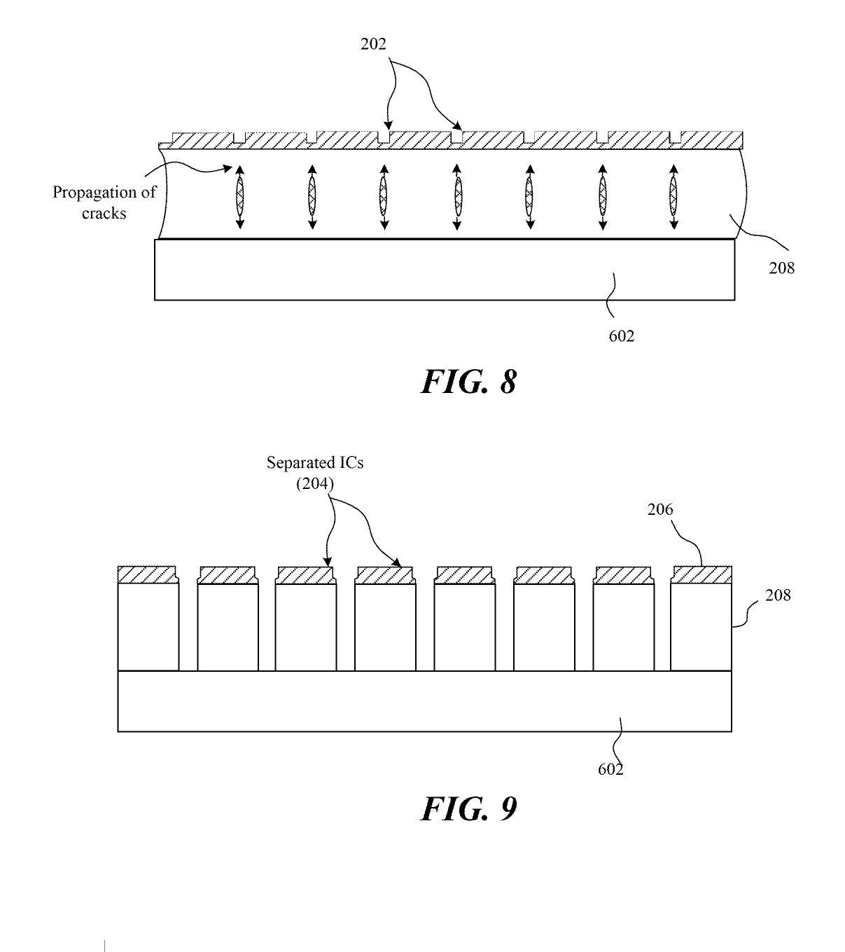

FIG. 8 illustrates propagation of cracks during wafer expansion;

FIG. 9 shows the separated ICs after wafer expansion; and

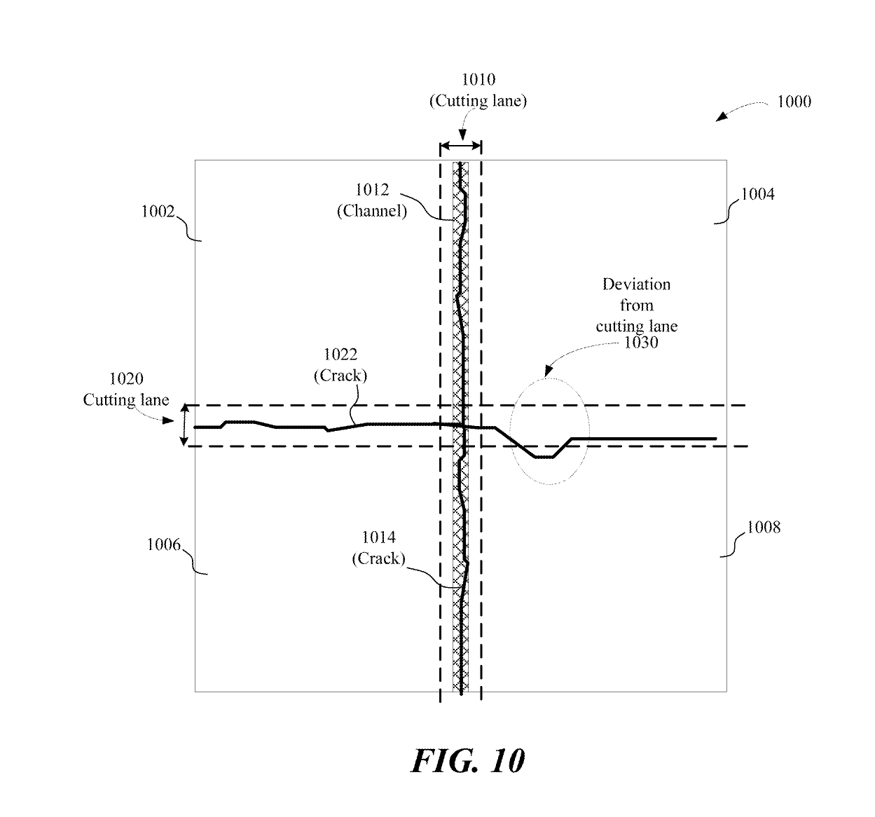

FIG. 10 illustrates propagation of cracks in the metallization layer with and without channels cut in the cutting lane of the metallization layer.

While the disclosure is amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the scope of the disclosure including aspects defined in the claims. In addition, the term “example” as used throughout this application is only by way of illustration, and not limitation.

Aspects of the present disclosure relate to separation of ICs on a semiconductor wafer. For example, various embodiments are directed to separating ICs in a wafer having a silicon substrate as a back-side of the wafer, and one or more metallization layers/active regions on the substrate on a front-side of the wafer.

Some embodiments are directed to a method for separating such a wafer into individual ICs. Channels are formed in the one or more metallization layers on a front-side of the wafer along respective lanes along which the ICs are to be separated. These (separation) lanes are located between ICs and extend between a front-side of the wafer at the metallization layer(s), and a backside of the wafer at the silicon substrate. After forming the channels, the backside of the silicon substrate is thinned, and laser pulses are applied via the backside of the silicon substrate to change the crystalline structure of the silicon substrate along the lanes. This change in the silicon structure weakens the silicon in the lanes. The changed portions in the silicon substrate and the channels facilitate the propagation of cracks in the silicon substrate along the lanes during expansion of the wafer, while mitigating propagation of cracks outside of the lanes. With this approach, wafer separation can be achieved while mitigating issues that can arise from the formation of cracks, and as discussed above.

In various embodiments, the changed portions of the silicon substrate are located within the lanes at various depths in the silicon substrate. For instance, in some embodiments, the changed portions may be offset from one or both of the metallization layer and from a backside of the silicon substrate. The figures depict exemplary embodiments in this regard. The positioning of the changed portions may be set to achieve desired structural support within the substrate (via unchanged portions in the lanes) and/or achieve a desired propagation of cracks during expansion of the wafer.

In various embodiments, the crystalline structure in the silicon substrate is changed as discussed above by applying laser pulses to the silicon substrate via the backside to first melt and then solidify the silicon substrate along the lanes. In some embodiments, the laser pulses are focused to converge at a depth in the silicon substrate at which the portions to be changed are located. In some embodiments, crystalline structure of the silicon substrate may be changed at multiple (e.g., >1) depths in the silicon substrate. For instance, in one embodiment, a first laser is used to modify a crystalline structure of portions located at a first depth in the silicon substrate and a second laser is used to modify a crystalline structure of portions located at a second depth in the silicon substrate. The two depths may be separated by a layer in the silicon substrate at which the crystalline structure of the silicon is not changed. Modification of the crystalline structure at different depths along the lanes of the silicon substrate may be desirable, e.g., for substrates that are thicker than 150 μm or composed of low ohmic material. While the embodiments are not so limited, for ease of explanation, the disclosed examples are primarily described with reference to modification of a crystalline structure at a single depth in the silicon substrate.

One or both of the duration of the laser pulses and interval between the laser pulses are set to suit particular embodiments. In some implementations, sequential laser pulses are applied with a delay between the pulses that is sufficient to prevent the temperature of the substrate from exceeding a threshold that would damage the integrated circuits. In these and/or other implementations, sequential laser pulses are applied with a delay that is set to control a rate at which the melted portions of the silicon are solidified. For example, a first rate of laser pulsing may be applied to melt the silicon while ensuring that ICs therein are not damaged. After melting, a different rate of laser pulsing (i.e., with an increased delay) may be applied to allow the melted silicon to solidify, while controlling the rate of solidification (e.g., by controlling the rate of cooling).

In some embodiments, the channels formed in the metallization layer are formed at a depth sufficient to achieve desired propagation of cracks in the metallization layer during wafer expansion. As explained in more detail in the following, the channels in the metallization layer assist to create a weak point in the metallization layer at which cracks will form in the metallization layer when subjected to expansive stresses during wafer expansion. In some embodiments, the formed channels have a depth that is less than a thickness of the metallization layer. Due to the portion of the metallization layer retained in the channels, a larger expansion force must be exerted before cracks are formed in the channels of the metallization layer. As a result, for some wafer structures, cracks will propagate more evenly in the silicon substrate after the stresses cause the metallization layer to break in the channels. In some embodiments, the channels are formed to have a depth that is 90% of a thickness of the metallization layer.

In some embodiments, various layers of support tape are placed on the substrate and/or metallization layer to support the wafer during processing and expansion of the wafer. For instance, in some embodiments, one or more layers of support tape are placed on the metallization layer prior to thinning the backside of the silicon substrate. Similarly, in some embodiments, after applying the laser to change the crystalline structure of the portions of the silicon substrate and prior to wafer expansion, a layer of support tape is place on the backside of the silicon substrate.

For ease of explanation, examples are primarily described with reference to a wafer comprising a silicon substrate and a metallization layer on the front-side of the wafer. However, the embodiments are not so limited. It is understood that a wafer to be diced may include other materials, layers and/or structures including, but not limited to, semiconductor layers, dielectric layers, isolation layers, metallization layers, and passivation layers.

FIG. 1 shows a flowchart of a method for separating ICs formed on a wafer, in accordance with one or more embodiments. The wafer includes a metallization layer on a front-side of a substrate. Channels are cut in a front-side metallization layer along the lanes using a cutting blade at block 102. The lanes are located between ICs formed on the wafer and extend between the front-side and the backside of the silicon substrate. A first layer of support tape is placed on the front-side of metallization layer at block 104. While using the support tape to support the wafer and mitigate cracking, the wafer is flipped at block 106 to orient the wafer front-side down. The backside of the wafer is thinned at block 108. After thinning the backside, a crystalline structure of portions of the silicon substrate is changed at block 110 by applying a laser via the backside of the silicon substrate. The changed portions are located within the lanes and are offset from the front-side and the backside of the silicon substrate. A second layer of support tape is placed on a backside of the substrate at block 112. While using the support tape to support the wafer and mitigate cracking, the wafer is flipped at block 114 to orient the wafer front-side up and the first layer of support tape is removed. ICs formed on the wafer are separated at block 116 by expanding the silicon substrate to propagate cracks along the lanes, while using the changed crystalline structure and the channels to mitigate cracking outside of the lanes.

FIGS. 2-9 illustrate separation of ICs formed on a wafer. FIG. 2A shows a top-view of a plurality of ICs (e.g., 204) formed on a wafer 200. FIG. 2B shows an enlarged portion of cross section I of the wafer 200 shown in FIG. 2A. The wafer includes a metallization layer 206 on a front-side of a silicon substrate 208. ICs 204 are formed in respective regions of the metallization layer. Separation lanes (e.g., 210) are located between ICs 204 formed on the wafer. The lanes (e.g., 210) extend from a backside of the silicon substrate to a front-side of the metallization layer. Channels 202 are cut in the front-side of the metallization layer along the lanes (e.g., 210).

FIG. 3 shows the wafer of FIG. 2 with support tape placed on the front-side of the wafer. In some implementations, the support tape 302 may include multiple layers of different types support tapes. For instance, in one implementation, the support tape 302 includes a layer of back grinding cover tape placed on the front-side of the metallization layer and a layer of dicing tape placed on a front-side of the back grinding cover tape. The back grinding tape and dicing tape support the wafer and protect the metallization layer during thinning of the silicon substrate. FIG. 4 shows the wafer of FIG. 3 oriented front-side down and having the backside of the silicon substrate 208 thinned. The substrate may be thinned using various methods including but not limited to planarization, and etching.

FIG. 5 shows the wafer of FIG. 4 with the crystalline structure changed in portions of the silicon substrate. The crystalline structure of portions (502) of the silicon substrate are changed by applying a laser 504 to the portions of the silicon substrate via the backside of the silicon substrate 208. As shown in FIG. 5, the portion of the substrate, in which the crystalline structure is changed is along the lanes 210 (i.e., aligned with the channels 202). In this example the portion of the substrate, in which the crystalline structure is changed is offset from the metallization layer and the backside of the silicon substrate. The offset leaves the crystalline structure of portions of the substrate immediately adjacent to the metallization layer and the backside intact.

In some embodiments, the crystalline structure is changed in the portions of the silicon substrate by applying pulses of a laser to the silicon substrate to melt silicon in the target portion and then quickly solidify the melted silicon. Due to the rate at which the silicon recrystalizes, the silicon has a different crystalline structure than that of the unchanged silicon substrate. As a result of the non-uniform crystalline structure, the silicon substrate is weakened at the changed portions. The duration between sequential laser pulses may be adjusted to control the rate at which the melted silicon recrystalizes. The duration between sequential laser pulses may also be adjusted to prevent the temperature of the substrate from exceeding a threshold that may damage the integrated circuits.

In some implementations, the laser pulses may be focused to converge as a point in the silicon substrate between the metallization layer and the backside of the silicon substrate. In this manner, the changed portion of the silicon may be limited to a region along the lanes that is offset from the front-side and the backside of the silicon substrate. The unchanged portions in the lanes adjacent to the metallization layer and backside of the substrate provide support for the wafer prior to expansion.

The wafer in FIG. 5 shows the crystalline structure of the silicon substrate modified at one depth in the silicon substrate. However, as indicated above, in some embodiments, the crystalline structure of the silicon substrate is modified at multiple depths separated by layers or regions at which the crystalline structure is not modified.

FIG. 6 shows the wafer of FIG. 5 with support tape 602 placed on the backside of the silicon substrate 208. FIG. 7 shows the wafer of FIG. 6 oriented front-side up and the first layer of support tape 302 removed from the front-side metallization layer.

The ICs are separated by expanding the wafer to form cracks along the lanes. FIG. 8 illustrates expansion of the wafer shown in FIG. 6 to propagate cracks along the lanes. During expansion, support for the substrate is provided by the metallization layer, which mitigates cracks from forming in the substrate. The channels in the metallization layer assist to create a weak point in the metallization layer at which cracks will form in the metallization layer when subjected to expansive stresses. As cracks form in the metallization layer along the lanes, the cracks propagate from the channels in the metallization layer and from the changed portion in the silicon substrate. As a result, cracks formed in the silicon substrates during expansion are directed toward the channels in the metallization layer. FIG. 9 shows the separated ICs 204 after wafer expansion.

In some embodiments, the channels formed in the metallization layer have a depth that is less than a thickness of the metallization layer. For instance, for a metallization layer of 10 μm thickness, the channels may have a depth that is less than or equal to 9 μm. Because a portion of the metallization layer is retained in the cutting layers, a larger expansion force must be exerted before cracks are formed in the channels of the metallization layer. Due to this larger force, cracks will propagate more evenly in the silicon substrate after the stresses cause the metallization layer to break in the channels.

FIG. 10 illustrates a top view of a wafer segment with cracks in a front-side metallization layer resulting from wafer expansion. In this example, the illustrated wafer portion 1000 includes four ICs 1002, 1004, 1006, and 1008 separated from each other by lanes 1010 and 1020. In this example, a channel 1012 is formed in cutting lane 1010 but not in cutting lane 1020. As a result of expansion, cracks 1014 and 1022 are formed in the lanes 1010 and 1020. As illustrated in FIG. 10, the crack 1014 in cutting lane 1010 is contained within the channel 1012 and thus is contained within the cutting lane 1010. In contrast, the crack 1022 formed in cutting lane 1020 without a channel meanders outside of the cutting lane at location 1030. As a result of crack 1022 propagating outside of cutting lane 1020, circuitry of IC 1008 may be damaged.

The embodiments are thought to be applicable to a variety of applications, which involve dicing of semiconductor wafers. Other aspects and embodiments will be apparent to those skilled in the art from consideration of the specification. While the present disclosure is amenable to various modifications and alternative forms, specifics thereof have been shown by way of example in the drawings and will be described in further detail. It should be understood that the intention is not to limit the disclosure to the particular embodiments and/or applications described. On the contrary, the intention is to cover all modifications, equivalents, and alternatives falling within the spirit and scope of the present disclosure.

What is claimed is:

1. A method for separating a wafer having a silicon substrate and a metallization layer on a front-side of the silicon substrate, the method comprising:
forming channels in the metallization layer along respective lanes, the lanes being located between integrated circuits in the metallization layer and extending between a front-side of the metallization layer and a backside of the silicon substrate;
thinning the backside of the silicon substrate;
after thinning the backside, changing a crystalline structure of portions of the silicon substrate, which are located in the lanes and offset from the backside and from the metallization layer, by applying a laser via the backside of the silicon substrate; and
separating the integrated circuits along the lanes by expanding the silicon substrate while using the changed crystalline structure and the channels, therein
propagating cracks in the silicon substrate along the lanes, and
mitigating cracking of the silicon substrate and metallization layer in regions outside of the lanes.

2. The method of claim 1, wherein changing the crystalline structure of portions of the silicon substrate includes changing the crystalline structure of portions of the substrate that are offset from both the metallization layer and the backside of the silicon substrate, and leaving the crystalline structure of portions of the substrate immediately adjacent the metallization layer and backside intact.

3. The method of claim 1, wherein changing the crystalline structure of portions of the silicon substrate includes applying laser pulses to the silicon substrate via the backside to melt and then solidify the silicon substrate along the lanes.

4. The method of claim 3, wherein applying the laser pulses includes focusing the laser to converge at a point in the silicon substrate between the metallization layer and the backside of the silicon substrate.

5. The method of claim 3, wherein applying the laser pulses includes applying sequential pulses separated by a duration of time sufficient to prevent the temperature of the substrate from exceeding a threshold that would damage the integrated circuits.

6. The method of claim 1, wherein the changing of the crystalline structure of portions in the silicon substrate includes:
changing the crystalline structure of first portions in the silicon substrate, which are located in the lanes and at a first depth in the silicon substrate; and
changing the crystalline structure of second portions in the silicon substrate, which are located in the lanes and at a second depth in the silicon substrate, the first and second depths in the silicon substrate being separated by a portion of the silicon substrate in the lanes in which the crystalline structure is not changed.

7. The method of claim 1, wherein the forming of the channels in the metallization layer includes forming channels having a depth that is less than a thickness of the metallization layer.

8. The method of claim 7, wherein the forming of the channels in the metallization layer includes forming channels having a depth that is 90% of a thickness of the metallization layer.

9. The method of claim 1, further comprising, after forming the channels in the metallization layer and prior to thinning the backside of the silicon substrate,
placing a first layer of support tape on the metallization layer; and
flipping the wafer to orient the wafer front-side down while using the support tape to support the wafer and mitigate cracking of the wafer.

10. The method of claim 9, further comprising: placing a dicing tape on a back-side of the first layer of support tape.

11. The method of claim 9,
wherein forming channels in the metallization layer includes forming channels that do not extend fully through the metallization layer, leaving an interface between the metallization layer and the silicon substrate intact;
wherein applying the laser includes focusing the laser to leave the crystalline structure of portions of the silicon substrate in the lanes adjacent the backside and the interface intact; and
further including using the metallization layer at the interface and the intact portions of the silicon substrate in the lanes to mitigate cracking of the wafer, prior to separating the integrated circuits along the lanes.

12. The method of claim 11, further comprising, after changing the crystalline structure of the portions of the silicon substrate and prior to separating the integrated circuits:
placing a second layer of support tape on the back-side of the wafer;
removing the first layer of support tape; and
flipping the wafer to orient the wafer front-side up while using the second layer of support tape, the metallization layer at the interface, and the intact portions of the silicon substrate in the lanes to mitigate cracking of the wafer while the integrated circuits are being separated.

13. The method of claim 12, further comprising, prior to flipping the wafer to orient the wafer front-side up, placing a layer of dicing tape on the back-side of the second layer of support tape.

14. An integrated circuit wafer, comprising:
a silicon substrate;
at least one metallization layer on a front-side of the silicon substrate;
a plurality of integrated circuits;
channels formed in the at least one metallization layer along respective lanes, the lanes being located between the integrated circuits and extending between a front-side of the at least one metallization layer and a backside of the silicon substrate; and
a plurality of portions in the silicon substrate, located within the lanes, having a crystalline structure that is different from a crystalline structure of the silicon substrate outside of the lanes, the plurality of portions in the silicon substrate and the channels configured to propagate cracks in the silicon substrate along the lanes and mitigate propagation of cracks outside of the lanes during expansion of the integrated circuit wafer.

15. The integrated circuit wafer of claim 14, wherein the plurality of portions in the silicon substrate have a crystalline structure that is characteristic of silicon that has been melted by laser pulses applied to a backside of the silicon substrate and thereafter solidified.

16. The integrated circuit wafer of claim 14, wherein the plurality of portions are offset from the metallization layer and a backside of the silicon substrate.

17. The integrated circuit wafer of claim 14, wherein the channels in the metallization layer have a depth that is less than a thickness of the metallization layer.

18. The integrated circuit wafer of claim 17, wherein the channels in the metallization layer have a depth that is less 90% of a thickness of the metallization layer.

19. The integrated circuit wafer of claim 14, wherein:
the plurality of portions in the silicon substrate are located at a first depth in the silicon substrate; and
the integrated circuit wafer further comprises:
a second plurality of portions in the silicon substrate, located within the lanes at a second depth in the silicon substrate that is different from the first depth, and having a crystalline structure that is different from a crystalline structure of the silicon substrate outside of the lanes, the first depth and the second depth separated by a portion of the silicon substrate at which the crystalline structure is consistent with the crystalline structure of the silicon substrate outside of the lanes.

20. A method for separating a wafer having a silicon substrate and a metallization layer on a front-side of the silicon substrate, the method comprising:
forming channels in the metallization layer along respective lanes, the lanes being located between integrated circuits in the metallization layer and extending between a front-side of the metallization layer and a backside of the silicon substrate, and the channels having a depth that is less than a thickness of the metallization layer;
after forming the channels in the metallization layer, placing a first layer of support tape on the metallization layer;
thinning the backside of the silicon substrate;
after thinning the backside, changing a crystalline structure of portions of the silicon substrate, which are located in the lanes and offset from the backside and from the metallization layer, by applying a laser via the backside of the silicon substrate to melt and then solidify the silicon substrate along the lanes, the application of the laser leaving the crystalline structure of portions of the substrate in the lanes and immediately adjacent the metallization layer and backside intact;
after changing the crystalline structure of the portions of the silicon substrate, placing a second layer of support tape on the back-side of the wafer and removing the first layer of support tape; and
separating the integrated circuits along the lanes by expanding the silicon substrate while using the changed crystalline structure and the channels, therein
propagating cracks in the silicon substrate along the lanes, and
mitigating cracking of the silicon substrate and metallization layer in regions outside of the lanes.
